(19) United States
(12) Patent Application Publication
(10) Pub. No.: US 2023/0087366 A1
(43) Pub. Date: Mar. 23, 2023

(54) CARRIER WAFER WITH MULTIPLE ANTIREFLECTIVE COATING LAYERS

(71) Applicant: International Business Machines Corporation, Armonk, NY (US)

(72) Inventors: Qianwen Chen, Chappaqua, NY (US); Michael P. Belyansky, Halfmoon, NY (US); John Knickerbocker, Monroe, NY (US); Akihiro Horibe, Yokohama (JP)

(21) Appl. No.: 17/447,948

(22) Filed: Sep. 17, 2021

(51) Int. Cl. G02B 1/115; G02B 1/14; H01L 23/00; H01L 21/02

(52) U.S. Cl. CPC G02B 1/115; G02B 1/14; H01L 23/562; H01L 21/02225

(57) ABSTRACT

A carrier wafer, a structure, and a method are disclosed. The carrier wafer includes a wafer layer having a first surface and a second surface opposite the first surface, a first antireflective coating (ARC) layer positioned on the first surface of the wafer layer, a second ARC layer positioned on a surface of the first ARC layer opposite the wafer layer, and a thin release layer positioned on a surface of the second ARC layer opposite the first ARC layer. The structure includes the carrier wafer and a semiconductor device substrate positioned over the thin release layer of the carrier wafer. The method includes obtaining a wafer layer, forming an ARC layer on a surface of the wafer layer, forming a second ARC layer on a surface of the first ARC layer opposite the wafer layer, and forming a thin release layer on the second ARC layer.

### BACKGROUND

The present disclosure relates to microelectronics packaging and, more specifically, to carrier wafers with multiple antireflective coating layers.

Semiconductor device manufacturing can include wafer level packaging (WLP) and panel level packaging (PLP) technology. In order to provide mechanical/structural support during WLP/PLP processing, assembly, and/or integration steps, device wafers, dies, panels, packages, and/or components can be releasably bonded to a carrier wafer, such as a glass or silicon carrier wafer. For example, a silicon carrier wafer can be bonded to a semiconductor device substrate (e.g., a silicon wafer) by a thin release layer. The thin release layer can be removed via laser ablation in order to debond the silicon carrier wafer.

### SUMMARY

Various embodiments are directed to a carrier wafer. The carrier wafer includes a wafer layer having a first surface and a second surface opposite the first surface, a first antireflective coating (ARC) layer positioned on the first surface of the wafer layer, a second ARC layer positioned on a surface of the first ARC layer opposite the wafer layer, and a thin release layer positioned on a surface of the second ARC layer opposite the first ARC layer. The carrier wafer can also include a third ARC layer positioned on the second surface of the wafer layer. In some embodiments, a warpage control layer is positioned over the second surface of the wafer layer. In these embodiments, a third ARC layer can be positioned over a surface of the warpage control layer opposite the wafer layer. The first and second ARC layers can be, respectively, silicon dioxide and silicon nitride layers. The wafer layer can be a silicon wafer, and the thin release layer can be a metallic film.

Additional embodiments are directed to a structure. The structure includes the carrier wafer that includes a wafer layer having a first surface and a second surface opposite the first surface, a first antireflective coating (ARC) layer positioned on the first surface of the wafer layer, a second ARC layer positioned on a surface of the first ARC layer opposite the wafer layer, and a thin release layer positioned on a surface of the second ARC layer opposite the first ARC layer. The structure also includes a semiconductor device substrate positioned over the thin release layer of the carrier wafer. The carrier wafer can also include a third ARC layer positioned on the second surface of the wafer layer. In some embodiments, a warpage control layer is positioned over the second surface of the wafer layer. In these embodiments, a third ARC layer can be positioned over a surface of the warpage control layer opposite the wafer layer. The first and second ARC layers can be, respectively, silicon dioxide and silicon nitride layers.

Further embodiments are directed to a method. The method includes obtaining a wafer layer, forming an ARC layer on a surface of the wafer layer, forming a second ARC layer on a surface of the first ARC layer opposite the wafer layer, and forming a thin release layer on the second ARC layer. The method can also include bonding a semiconductor device substrate to the thin release layer. In some embodiments, the thin release layer is then removed by laser ablation, and the surface of the second ARC layer is cleaned after the removal. The method can include forming a third ARC layer on the second surface of the wafer layer. Obtaining the wafer layer can include bonding two or more wafers together. In some embodiments, the method includes forming a warpage control layer on the second surface of the wafer layer. In these instances, a third ARC layer may be formed on a surface of the warpage control layer opposite the wafer layer.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 illustrates a schematic diagram of a carrier wafer structure, according to some embodiments of the present disclosure.

FIG. 2 is a schematic diagram illustrating an interaction between infrared (IR) radiation and a carrier wafer, according to some embodiments of the present disclosure.

FIG. 3A is a schematic diagram illustrating examples of carrier wafers, according to some embodiments of the present disclosure.

FIG. 3B is a chart illustrating effects of laser ablation power levels on equipment throughput (ETH) during semiconductor fabrication with carrier wafers, according to some embodiments of the present disclosure.

FIG. 4 is a schematic diagram illustrating a process of forming a carrier wafer with multiple ARC layers, according to some embodiments of the present disclosure.

While the invention is amenable to various modifications and alternative forms, specifics thereof have been shown by way of example in the drawings, and will be described in detail. It should be understood, however, that the intention is not to limit the invention to the particular embodiments described. Instead, the intention is to cover all modifications, equivalents, and alternatives falling within the spirit and scope of the invention.

### DETAILED DESCRIPTION

Embodiments of the present invention are generally directed to microelectronics packaging and, more specifically, to carrier wafers with multiple antireflective coating (ARC) layers and, optionally, a warpage control layer. While the present disclosure is not necessarily limited to such applications, various aspects of the disclosure may be appreciated through a discussion of various examples using this context.

Various embodiments of the present disclosure are described herein with reference to the related drawings, where like numbers refer to the same component. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus. Further, the word “providing” as used herein can refer to various actions such as creating, purchasing, obtaining, synthesizing, making available, etc. or combinations thereof.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “over,” “positioned on,” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

As used herein, the articles “a” and “an” preceding an element or component are intended to be nonrestrictive regarding the number of instances (i.e., occurrences) of the element or component. Therefore, “a” or “an” should be read to include one or at least one, and the singular word form of the element or component also includes the plural unless the number is obviously meant to be singular.

As used herein, the terms “invention” or “present invention” are non-limiting terms and not intended to refer to any single aspect of the particular invention but encompass all possible aspects as described in the specification and the claims.

Unless otherwise noted, ranges (e.g., time, concentration, temperature, etc.) indicated herein include both endpoints and all numbers between the endpoints. Unless specified otherwise, the use of a tilde (˜) or terms such as “about,” “substantially,” “approximately,” “slightly less than,” and variations thereof are intended to include the degree of error associated with measurement of the particular quantity based upon the equipment available at the time of filing the application. For example, “about” can include a range of ±8% or 5%, or 2% of a given value, range of values, or endpoints of one or more ranges of values. Unless otherwise indicated, the use of terms such as these in connection with a range applies to both ends of the range (e.g., “approximately 1 g-5 g” should be interpreted as “approximately 1 g-approximately 5 g”) and, in connection with a list of ranges, applies to each range in the list (e.g., “about 1 g-5 g, 5 g-10 g, etc.” should be interpreted as “about 1 g-about 5 g, about 5 g-about 10 g, etc.”).

It should also be understood that material compounds will be described in terms of listed elements, e.g., SiN, or SiGe. These compounds include different proportions of the elements within the compound, e.g., SiGe includes SiₓGe₍₁₋ₓ₎ where x is less than or equal to 1, and the like. In addition, other elements can be included in the compound and still function in accordance with the present principles. The compounds with additional elements will be referred to herein as alloys.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details. It should be noted that not all masking, patterning, and lithography processes are shown because a person of ordinary skill in the art would recognize where masking and patterning processes are utilized to form the identified layers and openings, and to perform the identified selective etching processes, as described herein.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching is any process that removes material from the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

Turning now to an overview of technologies that are more specifically relevant to aspects of the present disclosure, in general, the manufacture of microelectronics such as semiconductor devices involves formation of complex structures on device substrates via multiple process steps. Processes involved in forming semiconductor devices can include thin film deposition, photolithography, etching, ion implantation, wafer thinning, etc. Semiconductor device manufacturing can include wafer level packaging (WLP) and panel level packaging (PLP) technology. These technologies enable the manufacture of electronic devices that are small, light, and fast (e.g., handheld computing devices). In order to provide mechanical/structural support during WLP/PLP processing, assembly, and/or integration steps, device wafers, dies, panels, packages, and/or components can be releasably bonded to a carrier wafer, such as a glass or silicon carrier wafer. For example, a silicon carrier wafer can be bonded to a semiconductor device substrate (e.g., a silicon wafer) by a thin release layer.

However, challenges can arise in bonding and debonding of a device wafer, die(s), package, components, etc. to/from the carrier wafer. Mechanical debonding of silicon and glass carrier wafers, for example, can lead to yield losses and damage to device wafers. Mechanical debonding of silicon and glass carriers can also limit release and integration solutions compared to alternative separation or debonding techniques. For example, stress-induced warpage can negatively affect bonding and debonding. This can be caused by pre-existing stresses in the device wafer, panel, die(s), packages, components, etc. and/or stresses accumulated while bonded to the carrier wafer. For example, process steps, associated thermal budgets, structures, assembly, integration etc. can contribute to accumulated stresses.

Damage can also occur during release of a device wafer, panel, die(s), or other components from a carrier wafer, depending on the type of separation/debonding used. Silicon carrier wafers can be more difficult to debond than glass. For example, debonding a device substrate from a silicon carrier wafer via mechanical peeling can cause damage to the device. Another technique for debonding from a silicon carrier wafer involves laser ablation of a release layer with infrared (IR) energy. However, this approach can also cause damage when high laser power is used. Despite these challenges, silicon carriers offer many advantages over glass carriers, such as higher mechanical strength, better thermal conductivity, better warpage control, and compatibility with semiconductor equipment. Therefore, silicon carrier wafers that allow debonding release with lower power, high throughput, and without damage to wafers, dies, components, etc. would be beneficial.

Disclosed herein are support structures for semiconductor devices. The support structures include antireflective coating (ARC) layers. Herein, “carrier wafer” and “carrier” are used interchangeably to refer to support structures for device wafers, panels, dies, packages, components, integrated electronic assemblies, photonic assemblies, etc. Carrier wafers can include a wafer layer, such as a silicon (Si) wafer, and at least one additional layer in contact with front and/or back surfaces of the wafer layer. In some embodiments, the disclosed carrier wafers allow device wafer debonding by laser ablation using lower power than existing debonding techniques. For example, the disclosed ARC layers can increase the percent absorbance of laser energy relative to conventional structures. The disclosed structures can also provide improved resistance to wafer warpage in some embodiments. Some embodiments of the present disclosure include methods of making and using carrier wafers with ARC layers. The methods may further include forming a warpage control layer in the carrier wafer structures.

In various embodiments, carrier wafers disclosed herein may be used to process advanced node device wafers and fabricate integrated circuit chips that are thinned while being handled by a carrier wafer. The resulting integrated circuit chips can be distributed as a single wafer that has multiple unpackaged chips, or the resulting integrated circuit chips can be packaged after they are removed from the carrier wafer. In a packaged form, a chip may be mounted in a single chip package or in a multichip package. In various embodiments, the chip is then integrated with other chips, discrete circuit elements, and/or other signal processing devices as part of either an intermediate product (e.g., a wafer- or panel-level sub-assembly such as a packaged or module level sub-assembly, an assembled electronic module such as a motherboard, a system on a wafer or panel, etc.) or an end product, which in many applications would not include the carrier wafer.

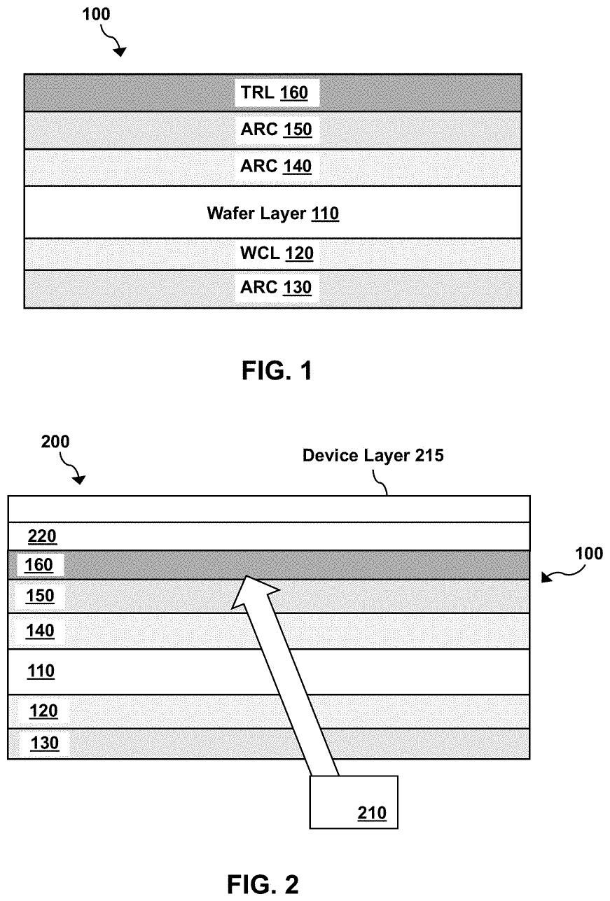

Referring now to the drawings, in which like numerals represent the same or similar elements, FIG. 1 illustrates a schematic diagram of a carrier wafer 100, according to some embodiments of the present disclosure. The carrier wafer 100 illustrated in FIG. 1 includes a wafer layer 110 (“wafer layer 110”). Wafer layer 110 may be a Si wafer (e.g., a layer of doped or undoped silicon). However, any appropriate substrate or material can be used for wafer layer 110 (e.g., glass, ceramic, germanium, gallium arsenide, ceramics, glass, sapphire, etc.).

In some embodiments, wafer layer 110 has a thickness in the range of about 100 μm-1000 μm (e.g., about 100 μm-200 μm, about 725 μm-775 μm, about 200 μm-800 μm, etc.) or greater (e.g., about 1 mm-3 mm). The thickness of wafer layer 110 can vary depending upon the material, application, structure, etc. For example, the thickness can be increased in order to compensate for stresses introduced as the length and/or width of the wafer 110 increase (e.g., when wafer layer 110 is a glass or ceramic carrier panel). A thicker wafer layer 110 can also be formed by bonding multiple wafers or panels (e.g., two layers, three layers, etc.) together.

Wafer layer 110 can be positioned over a warpage control layer (WCL) 120. However, WCL 120 may be omitted in other embodiments. WCL 120 can be a layer of silicon dioxide (SiO₂) or another dielectric such as silicon nitride (Si₃N₄), SiCN, HfO₂, a polymer such as a polyimide or benzocyclobutene, TiO₂, amorphous Si, etc. The thickness of WCL 120 can be tuned to compensate for warpage and device wafer bow (see below) and, in some embodiments, is between about 10 nm and 10 μm.

In some embodiments, WCL 120 is positioned over a first antireflective coating layer ARC 130. When WCL 120 is omitted, ARC 130 may be in contact with wafer layer 110. In further embodiments, ARC 130 or both of ARC 130 and WCL 120 can be omitted. An ARC layer (ARC 140) is positioned over the opposite side of wafer layer 110. In some embodiments, there are at least two ARC layers (ARC 140, ARC 150, etc.) between wafer layer 110 and a thin release layer (TRL) 160. In instances where WCL 120 and ARC 130 are included, there can one (ARC 140) or more than one ARC layer over the opposite side of wafer layer 110. The thicknesses of ARC 130, 140, and 150 can be about 1 mm or less (e.g., ˜10 μm-1 mm). Individual ARC layers 130, 140, and 150 can have differing thickness. However, at least two of ARC 130, 140, and 150 may have the same thickness in other embodiments.

TRL 160 is positioned between the antireflective coating layer(s) and a device wafer (not shown in FIG. 1). In FIG. 1, TRL 160 is over ARC 150. However, if additional ARC layers are included, TRL 160 can be positioned over the last ARC layer above ARC 150. That is, the ARC layers are positioned between wafer layer 110 and TRL 160. TRL 160 is a layer of material that can be used to releasably bond the device wafer. This is illustrated in FIG. 2. TRL 160 can be a film with a thickness between about 10 nm and 1 μm. For example, TRL can be a thin metal (e.g., Al, Ti, Cr, Pb, Pt, AlO₂, etc.) or polymer film (e.g., carbon rich/doped polymers, Light-To-Heat Conversion Release Coating (LTHC) from 3M™, BrewerBOND® 510, 530, or 701 from Brewer Science, SPIS-TA401E from Shin-Etsu Chemical Company, etc.). In other embodiments, TRL 160 can be a layer of a carbon material such as graphene or a layer of carbon nanotubes.

FIG. 2 is a schematic diagram 200 illustrating an interaction between infrared (IR) radiation and carrier wafer 100, according to some embodiments of the present disclosure. The IR radiation (represented by a block arrow in FIG. 2) can be supplied by a laser source 210 during a process of laser ablation. Laser ablation is used during semiconductor fabrication when removing a device wafer from a carrier wafer. Laser ablation provides sufficient power to remove (e.g., vaporize) a thin release layer bonding the device wafer to the carrier wafer. The IR radiation may include wavelengths in the range of about 1 μm-5 μm. For example, laser source 210 can emit wavelengths of about 0.75 μm-1.2 μm, about 1.2 μm-3 μm, etc. However, any wavelength of radiation appropriate for carrier wafer 100 can be used. For example, in instances where wafer layer 110 is made of glass, ultraviolet light may be used in ablation of TRL 160.

In FIG. 2, TRL 160 is positioned between ARC 150 and a device layer 215. Device layer 215 includes a substrate 220, such as a semiconductor wafer, which can be bonded to carrier wafer 100 via TRL 160. For example, substrate 220 can be a silicon wafer having undoped, p-doped, and/or n-doped regions. In some embodiments, substrate 220 may be another semiconductor such as silicon-germanium, graphene, amorphous silicon, polycrystalline silicon, an organic semiconductor, silicon carbide (SiC), gallium, gallium arsenide (GaAs), gallium nitride (GaN), indium gallium arsenide (InGaAs), etc.

There can be through substrate vias (not shown) extending at least partially through substrate 220 in some embodiments. Device layer 215 may also include at least one semiconductor device or component thereof formed on the surface of the substrate 220 opposite carrier wafer 100. Individual semiconductor devices and components are not illustrated in FIG. 2, but can include transistors, capacitors, wirings, etc. Device layer 215 components can include any appropriate components known in the art, as will be understood by persons of ordinary skill.

In some embodiments, carrier wafer 100 may be reused one or more times after removal of TRL 160 and device layer 215. For example, carrier wafer 100 may be cleaned and/or inspected after removal and used again. Cleaning may include chemical cleaning, oxygen ash cleaning, plasma ash cleaning, water cleaning, alternate cleaning treatments, or combinations thereof. Inspection may include optical and metrology measurements against specifications of carrier wafer quality with ARC layers and/or WCL and used again where specifications are met.

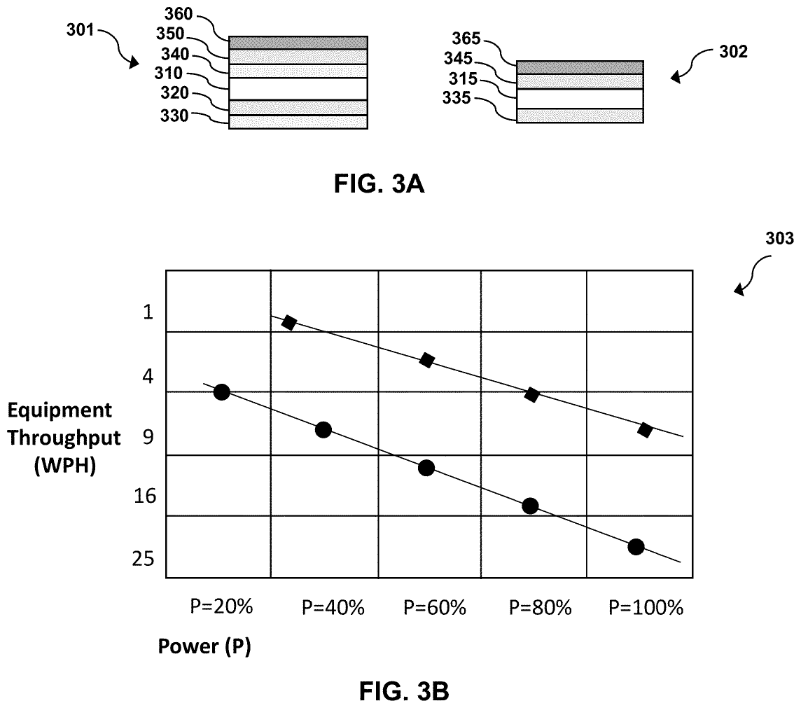

FIG. 3A is a schematic diagram illustrating examples of carrier wafers 301 and 302, according to some embodiments of the present disclosure. Carrier wafer 301 is a carrier wafer substantially similar to, or the same as, carrier wafer 100 (FIG. 1). Carrier wafer 301 includes a Si carrier wafer 310, a silicon dioxide wafer control layer (WCL) 320, two silicon nitride ARC layers (ARC 330 and ARC 350), a silicon dioxide ARC layer 340, and a TRL 360. Carrier wafer 302 is an example of a carrier wafer that only has a single ARC layer on each side of the wafer. Carrier wafer 302 includes a Si wafer 315, two silicon nitride layers 335 and 345, and a TRL 365. Both carrier wafers 302 can be bonded to device layers via TRLs 360 and 365, which can be substantially similar to TRL 160. Laser ablation can be used to remove TRLs 360 and 365 when debonding carrier wafers 301 and 302 from device wafers (not shown). Experimental results have also demonstrated that carrier wafer 301 can absorb three to four times more IR radiation than carrier wafer 302 during laser ablation.

FIG. 3B is a chart 303 illustrating effects of laser ablation power levels on equipment throughput (ETH) during semiconductor fabrication with carrier wafers 301 and 302, according to some embodiments of the present disclosure. When the power applied during laser ablation is greater, ETH may increase due to faster debonding. However, greater power may also cause damage to the device and/or carrier wafer. The ETH values (wafers-per-hour (WPH)) in chart 303 are based on experimental results involving a carrier wafer 301 (circles) disclosed herein and a carrier wafer 302 that only includes one ARC layer on each side of the carrier wafer (squares). Carrier wafers 301 and 302 are illustrated in FIG. 3A. The data points plotted in chart 303 represent normalized ETH values obtained when laser ablation/debonding is carried out at different power levels (% power). As discussed above, lower power and higher ETH are ideal in semiconductor fabrication. The results illustrated in FIG. 3B indicate that the disclosed carrier wafer 301, which has two ARC layers on one side of the carrier wafer and one ARC layer on the opposite side, can provide higher ETH at lower power levels than carrier wafers 302 having only a single ARC layer on each side of the carrier wafer.

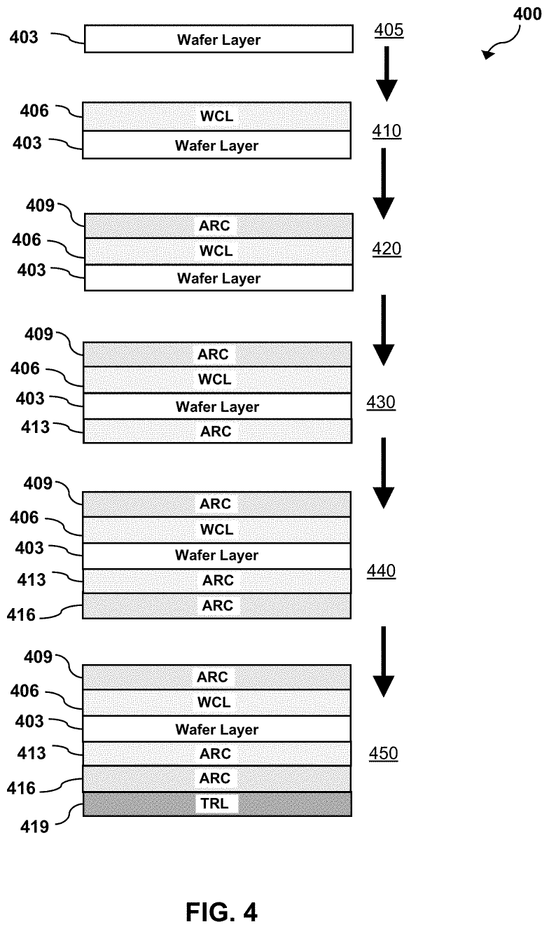

FIG. 4 is a schematic diagram illustrating a process 400 of forming a carrier wafer with multiple ARC layers and an optional warpage control layer, according to some embodiments of the present disclosure. Process 400 includes steps in forming a carrier wafer that can be similar to, or the same as, carrier wafer 100 (FIG. 1). In FIG. 4, layer positions are inverted relative to FIGS. 1 and 2. This is to illustrate a series of operations in process 400 and does not represent a difference in structure between carrier wafer 100 and the assembly formed at operation 450 (see below). However, embodiments of the present disclosure can include the formation of carrier wafers having structural differences such as different configurations, materials, additional layers, and/or other variations known to those of ordinary skill in the art.

A wafer layer 403 is provided. This is illustrated at operation 405. Wafer layer 403 may be formed in situ or obtained as a premade wafer. In some embodiments, wafer layer 403 is formed by bonding two or more wafers together. For example, two or more silicon or glass wafers can be bonded to form a silicon wafer layer or a glass wafer layer, respectively. Wafer layer 403 may also be another material such as those discussed with respect to wafer layer 110. In some embodiments, wafer layer 403 is a single crystalline or polycrystalline silicon material. In other embodiments, wafer layer 403 can be an amorphous silicon material. Wafer layer 403 may be an intrinsic (undoped) semiconductor. However, wafer layer 403 may include dopants in some embodiments, such as n-type dopants (e.g., antimony, arsenic, phosphorus, etc.) or p-type dopants (e.g., boron, aluminum, gallium, indium, etc.). In some embodiments, wafer layer 403 is substantially the same as, or similar to, wafer layer 110.

In some embodiments, process 400 includes forming a warpage control layer (WCL) 406 on a first surface of wafer layer 403. This is illustrated at operation 410. However, embodiments of the present disclosure can omit this operation and instead begin process 400 at operation 420 or 430 (see below). WCL 406 can be a dielectric material such as SiO₂ and can be deposited on the first surface of wafer layer 403 using any appropriate deposition technique (e.g., spin-coating, PECVD, ALD, etc.). Properties of WCL 406, such as thickness, can be varied in order to compensate for different types and degrees of wafer layer 403 warpage and/or device wafer bow. In some embodiments, WCL 406 can be adjusted for a tunable warpage range within about 1 mm (e.g., without substantially reducing absorption of radiation during laser ablation). In some embodiments, WCL 406 is substantially the same as, or similar to, WCL 120.

An ARC layer (ARC 409) can be deposited over WCL 406 or over wafer layer 403, if WCL 406 is omitted. This is illustrated at operation 420. In other embodiments, operation 420 and ARC 409 can be omitted. Operation 420 can use any appropriate deposition technique (e.g., spin-coating, PECVD, ALD, etc.) to apply the antireflective coating 409. Additional examples of deposition techniques that may be used to form ARC 409 and other ARC layers herein are discussed in greater detail above. ARC 409 can be a layer of a material such as SiO₂, Si₃N₄, SiCN, HfO₂, a polymer such as a polyimide or benzocyclobutene, TiO₂, amorphous Si, etc. In some embodiments, ARC 409 is substantially the same as, or similar to, ARC 130.

An ARC layer (ARC 413) is deposited on a side of wafer layer 403 that is opposite to ARC layer 409 and/or WCL 406, when layers 409 and 406 are included. This is illustrated at operation 430. ARC layer 413 can be deposited over wafer layer 403 using substantially the same techniques as those discussed above with respect to ARC 409 at operation 420. ARC 413 can be a layer of a material such as SiO₂, Si₃N₄, SiCN, HfO₂, a polymer such as a polyimide or benzocyclobutene, TiO₂, amorphous Si, etc. In some embodiments, ARC 413 is substantially the same as, or similar to, ARC 140. In embodiments where WCL 406 and ARC 409 have been included, process 400 may optionally proceed to operation 450 (see below). In the embodiment shown in FIG. 4 and embodiments where WCL 406 and/or ARC 409 are omitted, process 400 continues with operation 440.

At operation 440, a next ARC layer (ARC 416) is deposited on the same side of wafer layer 403 as at operation 430. ARC 416 can be deposited over ARC 413 using substantially the same techniques as those discussed at operation 420. ARC 416 can be a layer of a material such as SiO₂, Si₃N₄, SiCN, HfO₂, a polymer such as a polyimide or benzocyclobutene, TiO₂, amorphous Si, etc. In some embodiments, ARC 416 is substantially the same as, or similar to, ARC 150. In some embodiments, one or more additional ARC layers can be deposited over 416 by repeating operation 440.

A thin release layer (TRL) 419 is deposited over the final ARC layer (ARC 416) formed at operation 440. This is illustrated at operation 450. TRL 419 can be a layer of any material appropriate for removal via laser ablation (e.g., IR laser ablation). For example, TRL 419 can be a metal or polymer film such as those discussed above with respect to TRL 160 (FIG. 1). TRL 419 may be formed using a deposition process such as CVD, PVD (e.g., sputtering), ALD, or other deposition processes (see above). In some embodiments, TRL 419 is substantially the same as, or similar to, TRL 160.

While not shown in FIG. 4, a device wafer (e.g., device substrate 220) may be bonded to, and in direct contact with, TRL 419. However, there may be one or more intermediate layers (e.g., an adhesive layer) deposited over TRL 419 prior to bonding the device wafer in other embodiments. Techniques for bonding device wafers to thin release layers of carrier wafers that may be used are known to those of ordinary skill in the art. As discussed with respect to FIG. 2, laser ablation can be used to remove TRL 419, debond the carrier wafer from the device layer, and reuse the carrier wafer after cleaning, inspection, etc.

The processes discussed herein, and their accompanying drawings, are not to be construed as limiting. One skilled in the art would recognize that a variety of techniques may be used that vary in conditions, components, methods, etc., which ultimately result in carrier wafers with two or more ARC layers. In addition, the conditions can optionally be changed over the course of a process. Further, in some embodiments processes can be added, omitted, or carried out in alternate orders, while still remaining within the scope of the disclosure, as will be understood by a person of ordinary skill in the art. It should also be noted that processes can be carried out by a single entity, or by multiple entities. For example, a first entity may fabricate a carrier wafer, and a second entity may use the carrier as a removable support structure.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A carrier wafer, comprising:
a wafer layer having a first surface and a second surface opposite the first surface;
a first antireflective coating (ARC) layer positioned on the first surface of the wafer layer;
a second ARC layer positioned on a surface of the first ARC layer opposite the wafer layer; and
a thin release layer positioned on a surface of the second ARC layer opposite the first ARC layer.

2. The carrier wafer of claim 1, further comprising a third ARC layer positioned on the second surface of the wafer layer.

3. The carrier wafer of claim 1, further comprising a warpage control layer positioned on the second surface of the wafer layer.

4. The carrier wafer of claim 3, further comprising a third ARC layer positioned on a surface of the warpage control layer opposite the wafer layer.

5. The carrier wafer of claim 1, wherein the first ARC layer is a silicon dioxide layer, and the second ARC layer is a silicon nitride layer.

6. The carrier wafer of claim 1, wherein the wafer layer is a silicon wafer.

7. The carrier wafer of claim 1, wherein the thin release layer is a metallic film.

8. A structure, comprising:
a carrier wafer, comprising:
a wafer layer having a first surface and a second surface opposite the first surface;
a first antireflective coating (ARC) layer positioned on the first surface of the wafer layer;
a second ARC layer positioned on a surface of the first ARC layer opposite the wafer layer; and
a thin release layer positioned on a surface of the second ARC layer opposite the first ARC layer; and
a semiconductor device substrate positioned over the thin release layer.

9. The structure of claim 8, wherein the wafer layer comprises a silicon wafer.

10. The structure of claim 8, wherein the carrier wafer further comprises a third ARC layer, wherein the third ARC layer is positioned on the second surface of the wafer layer.

11. The structure of claim 8, wherein the carrier wafer further comprises a warpage control layer positioned on the second surface of the wafer layer.

12. The structure of claim 11, wherein the carrier wafer further comprises a third ARC layer positioned on a surface of the warpage control layer opposite the wafer layer.

13. The structure of claim 8, wherein the first ARC layer is a silicon dioxide layer, and the second ARC layer is a silicon nitride layer.

14. A method, comprising:
obtaining a wafer layer having a first surface and a second surface opposite the first surface;
forming a first antireflective coating (ARC) layer on the first surface of the wafer layer;
forming a second ARC layer on a surface of the first ARC layer opposite the wafer layer; and
forming a thin release layer on a surface of the second ARC layer opposite the first ARC layer.

15. The method of claim 14, further comprising bonding a semiconductor device substrate to the thin release layer.

16. The method of claim 15, further comprising:
removing the thin release layer by laser ablation; and
cleaning the surface of the second ARC layer after the removing.

17. The method of claim 14, further comprising forming a third ARC layer on the second surface of the wafer layer.

18. The method of claim 14, wherein the obtaining the wafer layer comprises bonding two or more wafers together.

19. The method of claim 14, further comprising forming a warpage control layer on the second surface of the wafer layer.

20. The method of claim 19, further comprising forming a third ARC layer on a surface of the warpage control layer opposite the wafer layer.
